(19) United States
(12) Patent Application Publication
(10) Pub. No.: US 2010/0207669 A1
(43) Pub. Date: Aug. 19, 2010

(54) FREQEUNCY ADJUSTING APPARATUS AND THE METHOD THEREFOR

(75) Inventors: Sheng-Chun Chueh, Shindian (TW); Wei-Jen Huang, Shindian (TW)

Correspondence Address: ROGER H. CHU, 19499 ERIC DRIVE, SARATOGA, CA, 95070, US

(73) Assignee: IDEACOM TECHNOLOGY CORPORATION (TAIWAN), Shindian (TW)

(21) Appl. No.: 12/388,544

(22) Filed: Feb. 19, 2009

(51) Int. Cl. H03B 19/00

(52) U.S. Cl. 327/113

(57) ABSTRACT

The invention relates to a frequency adjusting apparatus and the method therefor comprising an adjusting module, a comparing module, a processing module and an operating module. The adjusting module generates a frequency signal according to a predetermined signal after receiving a trigger signal and generates N adjusting signal according to N processing signal. The comparing module compares the N adjusting signal with the predetermined signal according to a predetermined manner and generates N comparing result. The processing module generates N processing signal according to the N comparing result. The operating module executes a specific operation with M adjusting signal of the N adjusting signal matching the predetermined rule and generates a operation signal, wherein the frequency of the operation signal is approximately equal to which of the predetermined signal. Wherein N and M are natural numbers and N≧M≧1, the adjusting module adjusts the operation frequency according to the operation signal.

### BACKGROUND OF THE INVENTION

1. Field of the Invention

The invention is related to a frequency adjusting apparatus, and more specifically related to a frequency adjusting apparatus for adjusting operation frequency of an electronic device.

2. Description of the Prior Art

Generally speaking, frequency of electronic element is generated by oscillators which can divide into two types which are crystal oscillators and resistor-capacitor oscillators respectively. The accuracy of the crystal oscillator is better than the Resistor-capacitor oscillator but also cost more corresponding. With this reason, the resistor-capacitor oscillator is used in various kinds of electronic products. The resistor-capacitor oscillator is consists of resistor and capacitor to generate the resonant characteristics but both the resistance of the resistor and the capacitance of the capacitor have inaccuracy affected by the manufacturing process and varying of the environment (for example: the difference of the temperatures). In general the error of the resistance of resistor is about 5% to 20% and the error of the capacitance of the capacitor is about 20% to 30%. Accordingly, the error of the resistor-capacitor oscillator is about 50% or more. The error of the resistor-capacitor oscillator has disadvantage of the oscillating frequency is unstable which may cause the back end circuit out of function.

There are many kinds of elements in an electronic product. It must executing the calibration of the frequency of those elements into the same level to make sure the accuracy of the transmitted data, otherwise it maybe has problem of data transmitting error caused by the error frequency that can't transmit the data completely or even the data transmitted by the transmitting terminal but the receiving terminal can't read out the transmitted data accuracy.

Please referring to FIG. 1, FIG. 1 is a schematic diagram of transmitting signal transmitted by a data transmitting device. In general, the data transmitting device includes a transmitting terminal and a receiving terminal for executing data transmitting operation, as shown in FIG. 1, the signal S is transmitted by the transmitting terminal which includes start frame, data frame and end frame. The start frame is used for declaring the beginning of data transmitting or receiving, and the end frame is used for declaring the end of the data in the data frame. As the arrow 1, which respects the frequency received at the receiving terminal is faster than the transmitting terminal, in this condition, it has the problem that the transmitting terminal error determines the data in the data frame has been transmitting completely and then stops receiving the data even if data in the data frame is still transmitting in the real. So in this condition, the data transmitting device can't accomplish data receiving that stored in the data frame. On the contrary, arrow 2 respects the frequency of the receiving terminal is slow than the frequency of the transmitting terminal, in this condition, it has problem that the transmitting terminal continued receiving the data even if the data in the data frame has been completely transmitted already. No matter which one of the conditions described above, it causes problem of data transmitting and can't accomplish data transmitting operation.

As mentioned above, how to provide user a frequency adjusting apparatus and the method therefor which can adjust and calibrate the frequency of the electronic product and further control the operation of the elements in the electronic product according to the adjusted frequency to prevent the error of the oscillating frequency from affecting the function of the back end circuit or the whole electronic product, which is became an important topic of technology of frequency adjusting or calibrating.

### SUMMARY OF THE INVENTION

It is therefore a primary objective of the present invention to provide a frequency adjusting apparatus and the method therefor for adjusting the error of the oscillating frequency to match the predetermined frequency and then executes the data transmitting.

One embodiment of the present invention provides a frequency adjusting apparatus comprising an adjusting module, a comparing module, a processing module and an operating module. The adjusting module is used for receiving a trigger signal, generating a frequency signal according to a predetermined signal and then adjusting the frequency signal according to N processing signal with a first predetermined manner to generating N adjusting signal. The comparing module is coupled to the adjusting module for comparing the N adjusting signal with the predetermined signal according to a predetermined rule to generate N compared result correspondingly. The processing module coupled to the comparing module is used for generating the N processing signal according to the N compared result with a second predetermined manner. When the N compared result respecting that both the M adjusting signal of the N adjusting signal and the predetermined signal matching the predetermined rule, the operating module coupled to the comparing module is used for executing a specific operation with the M adjusting signal to generate a operation signal, wherein the frequency of the operation signal is approximately equal to the frequency of the predetermined signal, N and M are natural number respectively and N≧M≧1, the adjusting module adjusts the operation frequency therein according to the operation signal.

Another embodiment of the present invention provides a frequency adjusting method comprising following steps: receiving a trigger signal and then generating a frequency signal according to a predetermined signal; adjusting the frequency signal according to N processing signal with a first predetermined manner to generate N adjusting signal, wherein N is a natural number and N≧1; comparing the N adjusting signal with the predetermined signal according to a predetermined rule and generating N compared result correspondingly; generating the N processing signal according to the N compared result with a second predetermined manner; executing a specific operation with the M adjusting signal when the N compared result respecting that the N adjusting signal and the predetermined signal matching the predetermined rule, wherein the frequency of the operation signal is approximately equal to the frequency of the predetermined signal, wherein M is a natural number and N≧M≧1 and then adjusting an operation frequency of an electronic device according to the operation signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of transmitting signal transmitted by a data transmitting device.

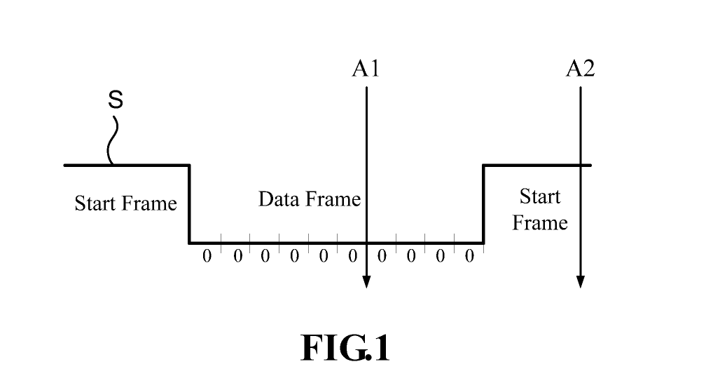

FIG. 2 is schematic diagram of an embodiment of the frequency adjusting apparatus according to the present invention.

FIG. 3 is a schematic diagram of an embodiment of the specific operation of the frequency adjusting apparatus according to the present invention.

FIG. 4 is a flowchart diagram of an embodiment of the frequency adjusting method according to the present invention.

### DETAILED DESCRIPTION

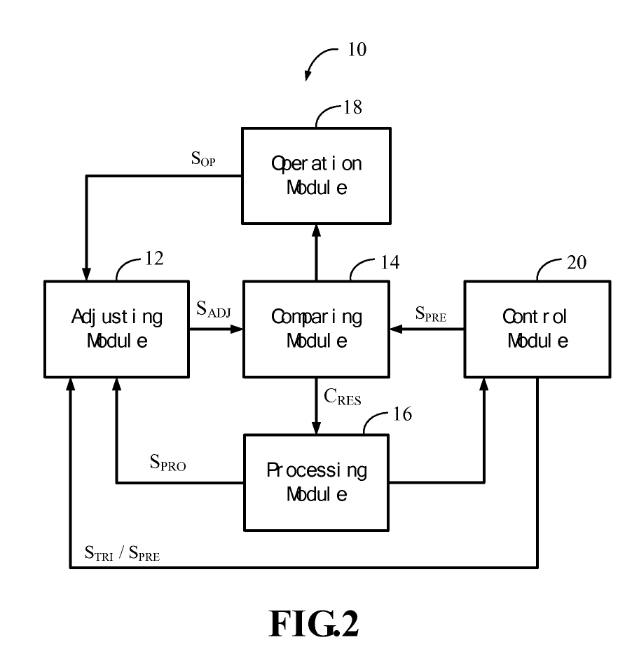

Please referring to FIG. 2, FIG. 2 is schematic diagram of an embodiment of the frequency adjusting apparatus according to the present invention. As shown in FIG. 2, the present invention is a frequency adjusting apparatus 10 comprising an adjusting module 12, a comparing module 14, a processing module 16 and an operating module 18. The adjusting module 12 is used for receiving a trigger signal S_{TRI}, generating a frequency signal according to a predetermined signal S_{PRE} and generating N adjusting signal S_{ADJ} by adjusting the frequency signal according to N processing signal S_{PRO} with a first predetermined manner. The comparing module 14 coupled to the adjusting module 12 is used for comparing the N adjusting signal S_{ADJ} with the predetermined signal S_{PRE} according to a predetermined rule and generating N compared result C_{RES} correspondingly. The processing module 16 coupled to the comparing module 14 is used for generating the N processing signal S_{PRO} according to the N compared result C_{RES} with a second predetermined manner. The operating module 18 coupled to the comparing module 16 is used for executing a specific operation with M adjusting signal S_{ADJ} to generate a operation signal S_{OP} when the N compared result C_{RES} respecting that the M adjusting signal S_{ADJ} of the N adjusting signal S_{ADJ} and the predetermined signal S_{PRE} matching the predetermined rule, wherein the frequency of the operation signal S_{OP} is approximately equal to the frequency of the predetermined signal S_{PRE}. Wherein N and M are nature number respectively, and N≧M≧1. The adjusting module 12 adjusts the operation frequency therein according to the operation signal S_{OP}.

The frequency adjusting apparatus 10 further comprises a control module 20 coupled to adjusting module 12, the comparing module 14 and the processing module 16 for generating the trigger signal S_{TRI} and the predetermined signal S_{PRE}, transmitting the trigger signal S_{TRI} and the predetermined signal S_{PRE} to the adjusting module 12 to trigger the adjusting module 12 to execute the frequency adjusting operation. As the actual operation, the control module 20 transmits the trigger signal to the adjusting module 12 to alert the adjusting module 12 for preparing the frequency adjusting operation and then the control module 20 further transmits the predetermined signal S_{PRE} to stat executing the frequency adjusting. In one of the embodiment, the frequency of the trigger signal S_{TRI} is less than the frequency of the predetermined signal S_{PRE}. In another embodiment, the frequency adjusting apparatus 10 further comprises a storing module (not shown) coupled between the comparing module 14 and the operating module 18 for storing M adjusting signal S_{ADJ} when both the M adjusting signal S_{ADJ} of the N adjusting signal S_{ADJ} and the predetermined signal S_{PRE} matching the predetermined rule. In this embodiment, the frequency adjusting apparatus 10 stores the M adjusting signal S_{ADJ} into the storing module (not shown) at first and then the operating module 18 reads the M adjusting signal S_{ADJ} stored in the storing module (not shown) to generate a operation signal S_{OP} when the comparing module 14 accomplish the comparing operation and finally the adjusting module 12 adjusts the output frequency therein according to the operation signal S_{OP} to complete the frequency adjusting operation.

The first predetermined manner is that adjusting an Nth adjusting signal S_{ADJ} different from an N-1th adjusting signal S_{ADJ} a predetermined unit. In one embodiment, the predetermined unit is a byte; the adjusting module 12 adjusts the adjusting signal S_{ADJ} a byte in sequence each time. The second predetermined manner is to generate an N-1th processing signal when an N-1th compared result respecting that an N-1th adjusting signal S_{ADJ} and the predetermined signal S_{PRE} mismatching the predetermined rule and stop generating an Nth processing signal when an Nth compared result respecting that both an Nth adjusting signal S_{ADJ} and the predetermined signal matching the predetermined rule. In another embodiment, the second predetermined manner is to generate an N-1th processing signal when an N-1th compared result respecting that both an N-1th adjusting signal S_{ADJ} and the predetermined signal matching the predetermined rule, and stop generating an Nth processing signal when an Nth compared result respecting that the predetermined signal S_{PRE} and an Nth adjusting signal S_{ADJ} mismatching the predetermined rule.

The predetermined rule is that the frequency of the M adjusting signal S_{ADJ} approximately equal to the frequency of the predetermined signal S_{PRE} or the difference of the frequency of the M adjusting signal S_{ADJ} and the frequency of the predetermined signal S_{PRE} less than 10%. The specific operation is to get a middle value of the M adjusting signal S_{ADJ} for generating a middle frequency and further generating the operation signal S_{OP} according to the middle frequency.

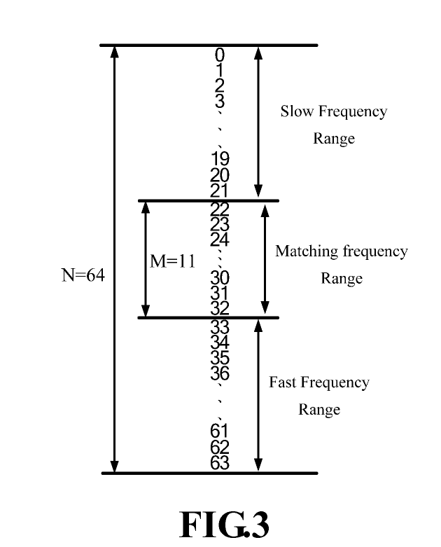

Please referring to the FIG. 3, FIG. 3 is a schematic diagram of an embodiment of the specific operation of the frequency adjusting apparatus according to the present invention. FIG. 3 is used for explaining the N adjusting signal, M adjusting signal S_{ADJ} and the specific operation. In this embodiment, N=64, M=11, when executing the frequency adjusting operation, user controls the control module 20 to generate the trigger signal S_{TRI} and the predetermined signal S_{PRE}. If user wants to adjust the frequency of the operation signal S_{OP} to 9600 bps, the frequency of the predetermined signal S_{PRE} generated by the control module 20 is set to 9600 bps and the frequency of the trigger signal S_{TRI} is set to 300 bps. Due to the frequency of predetermined signal S_{PRE} is far different from which of the trigger signal S_{TRI}, the adjusting module 12 can determine the received signal the same as the trigger signal S_{TRI} easily to preparer the frequency adjusting operation. After the control module 20 transmitting the trigger signal S_{TRI} to the adjusting module 12, the control module 20 transmits the predetermined signal S_{PRE} to the adjusting module 12 thereafter. The adjusting module 12 detects the predetermined signal S_{PRE} according to the frequency therein and then transmits the detected predetermined signal S_{PRE} to the comparing module 14 to generate the compared result C_{RES}. When the compared result C_{RES} is that the predetermined signal S_{PRE} mismatching the predetermined rule, the processing module 16 generates the processing signal S_{PRO} for controlling the adjusting module 12 to adjust the adjusting signal S_{ADJ} which generated last time for executing the comparing operation continued (as shown in the slow frequency range). It must be noticed that even when the compared result C_{RES} matching the predetermined rule already, the adjusting module 12 remains adjusting the adjusting signal S_{ADJ} continued to generates the new adjusting signal S_{ADJ} to execute comparing operation in sequence until the compared result C_{RES} mismatching the predetermined rule again (as shown in the matching frequency range) to stop generating next adjusting signal S_{ADJ} for finding out the frequency range of the adjusting signal S_{ADJ} which matching the predetermined rule. The operating module 18 gets the middle frequency of the adjusting signal S_{ADJ} in the matching frequency range which matching the predetermined rule to be the operation frequency of the adjusting module 12 to make sure the accuracy of the frequency and accomplish the frequency adjusting operation. As the same manner, if the compared result respecting that the frequency is in the fast frequency range; it also can adjust and calibrate the frequency to the same frequency of adjusting signal S_{ADJ} by using the same manner.

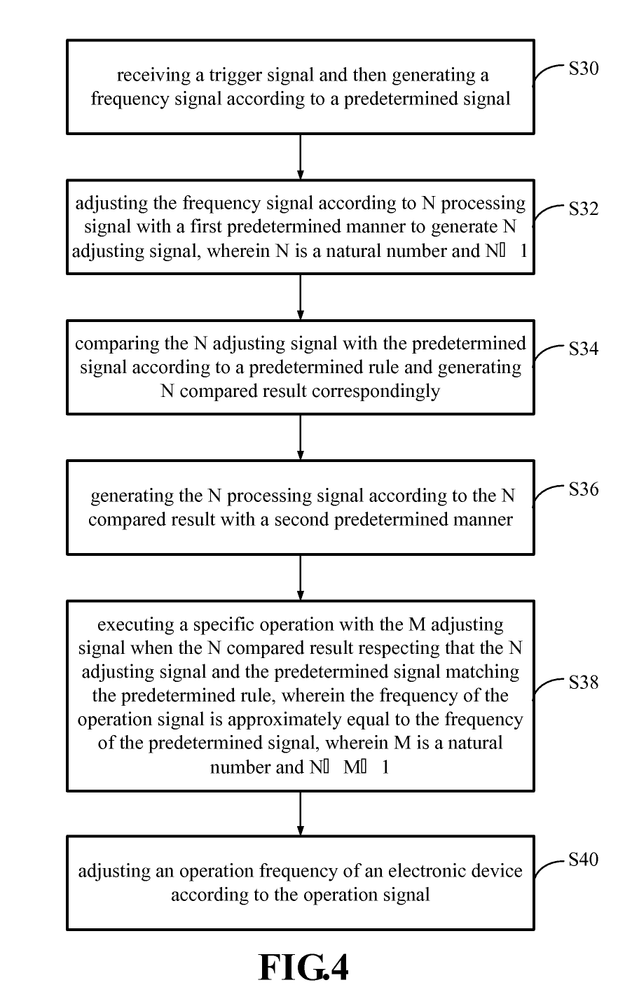

Please referring to FIG. 4, FIG. 4 is a flowchart diagram of an embodiment of the frequency adjusting method according to the present invention. As shown in FIG. 4, the present invention is a frequency adjusting method comprising the following steps:

Step 30: receiving a trigger signal and then generating a frequency signal according to a predetermined signal; in the other word, the frequency adjusting method begins to execute the frequency adjusting operation when receives the trigger signal.

Step 32: adjusting the frequency signal according to N processing signal with a first predetermined manner to generate N adjusting signal, wherein N is a natural number and N≧1; In one embedment, the first predetermined manner is to adjust an Nth adjusting signal to an N-1th adjusting signal with a predetermined unit. Wherein the predetermined unit is a byte.

S34: comparing the N adjusting signal with the predetermined signal according to a predetermined rule and generating N compared result correspondingly;

S36: generating the N processing signal according to the N compared result with a second predetermined manner. In one of the embedment, the second predetermined manner is to generate an N-1th processing signal when an N-1th compared result respecting to the predetermined signal and an N-1th adjusting signal mismatching the predetermined rule. In another embedment, the second predetermined manner is to generate an N-1th processing signal when an N-1th compared result respecting that both an N-1th adjusting signal and the predetermined signal matching the predetermined rule, and stop generating an Nth processing signal when an Nth adjusting signal matching the predetermined rule. In the other word, this step generates the N-1th processing signal when the N-1th compared result respecting that both the predetermined signal and the N-1th adjusting signal matching the predetermined rule, but stopping to generate an N processing signal when the Nth compared result respecting that the predetermined signal and the Nth adjusting signal mismatching the predetermined rule. Because the Nth processing signal is not been generated, the step S32 stops will generate the adjusting signal correspondingly.

S38: executing a specific operation with the M adjusting signal when the N compared result respecting that both the N adjusting signal and the predetermined signal matching the predetermined rule, wherein the frequency of the operation signal is approximately equal to the frequency of the predetermined signal, M is a natural number and N≧M≧1;

In one of the embodiment, the predetermined rule is that the frequency of N adjusting signal approximately equal to the frequency of the predetermined signal. In another embodiment, the predetermined rule is that the difference between the frequency of the N adjusting signal and the frequency of the predetermined signal less than 10%.

The specific operation is to get a middle value of the frequency of the M adjusting signal for generating a middle frequency and then generating the operation signal according to the middle frequency. In the frequency adjusting method of this invention, the predetermined rule and the specific operation can be decided by the user according to the real condition, the embodiment described above is used for explaining the processing steps but not limited to this invention.

S40: adjusting an operation frequency of an electronic device according to the operation signal.

As mentioned above, the present invention provides a frequency adjusting apparatus and method adjusting the operation frequency by a digital manner, which adjusts the operation frequency of another electronic device according to a predetermined signal to make sure the operation frequency is the same as which of the predetermined signal and then executing the following data transmitting operation. The specific operation is that getting a middle value of the frequency of the M adjusting signal to generate a middle frequency and then generating the operation signal according to the middle frequency not only adjust the difference of capacitance of the resistor-capacitor oscillator cause by the inaccuracy affected of the manufacturing process or the varying of the environment. No matter what kind of the oscillator can adjust the operation frequency of the electronic element therein via the frequency adjusting apparatus and the method of this present invention and prevent the problem cause by the difference of the frequency and enhance the accuracy of the oscillator.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A frequency adjusting apparatus, comprising:
a adjusting module for receiving a trigger signal, generating a frequency signal according to a predetermined signal and generating N adjusting signal by adjusting the frequency signal according to N processing signal with a first predetermined manner, wherein N is a natural number and N≧1;
a comparing module coupled to the adjusting module for comparing the N adjusting signal with the predetermined signal according to a predetermined rule and generating N compared result correspondingly;
an processing module coupled to the comparing module for generating the N processing signal according to the N compared result with a second predetermined manner; and
an operating module coupled to the comparing module for executing a specific operation with the M adjusting signal to generate a operation signal when the N compared result respecting that both M adjusting signal of the N adjusting signal and the predetermined signal matching the predetermined rule, wherein the frequency of the operation signal is approximately equal to the frequency of the predetermined signal, M is nature number, and N≧M≧1;
wherein the adjusting module adjusts the operation frequency according to the operating signal therein.

2. The frequency adjusting apparatus of claim 1, wherein further comprises a control module coupled to the adjusting module, the comparing module and the processing module, for generating the trigger signal and the predetermined signal and transmits the trigger signal and the predetermined signal to the adjusting module.

3. The frequency adjusting apparatus of claim 1, wherein the first predetermined manner is that adjusts an Nth adjusting signal to an N-1th adjusting signal a predetermined unit.

4. The frequency adjusting apparatus of claim 3, wherein the predetermined unit is a byte.

5. The frequency adjusting apparatus of claim 1, wherein the second predetermined manner is to generate an N-1th processing signal when an N-1th compared result respecting that an N-1th adjusting signal and the predetermined signal mismatching the predetermined rule and to stop generating an Nth processing signal when an Nth compared result respecting that both an Nth adjusting signal and the predetermined signal matching the predetermined rule.

6. The frequency adjusting apparatus of claim 1, wherein the second predetermined manner is to generate an N-1th processing signal when an N-1th compared result respecting that both an N-1th adjusting signal and the predetermined signal matching the predetermined rule, and stop generating an Nth processing signal when an Nth compared result respecting that the predetermined signal and an Nth adjusting signal mismatching the predetermined rule.

7. The frequency adjusting apparatus of claim 1, wherein the predetermined rule is that the frequency of the N adjusting signal approximately equal to the frequency of the predetermined signal.

8. The frequency adjusting apparatus of claim 1, wherein the predetermined rule is that the difference of the frequency of the N adjusting signal and the frequency of the predetermined signal less than 10%.

9. The frequency adjusting apparatus of claim 1, wherein the control module further comprises a storing module coupled to the comparing module and the operating module for storing the M adjusting signal when both the M adjusting signal of the N adjusting signal and the predetermined signal match the predetermined rule.

10. The frequency adjusting apparatus of claim 9, wherein the specific operation is to get a middle value of the M adjusting signal for generating a middle frequency and further generating the operation signal according to the middle frequency.

11. A frequency adjusting method, which comprising the following steps:
(a) receiving a trigger signal and then generating a frequency signal according to a predetermined signal;
(b) adjusting the frequency signal according to N processing signal with a first predetermined manner to generate N adjusting signal, wherein N is a natural number and N≧1;
(c) comparing the N adjusting signal with the predetermined signal according to a predetermined rule and generating N compared result correspondingly;
(d) generating the N processing signal according to the N compared result with a second predetermined manner;
(e) executing a specific operation with the M adjusting signal when the N compared result respecting that both the N adjusting signal and the predetermined signal matching the predetermined rule, wherein the frequency of the operation signal is approximately equal to the frequency of the predetermined signal, wherein M is a natural number and N≧M≧1; and
(f) adjusting an operation frequency of an electronic device according to the operation signal.

12. The frequency adjusting method of claim 11, wherein the first predetermined manner is to adjust an Nth adjusting signal to an N-1th adjusting signal with a predetermined unit.

13. The frequency adjusting method of claim 10, wherein the predetermined unit is a byte.

14. The frequency adjusting method of claim 13, wherein the second predetermined manner is to generate an N-1th processing signal when an N-1th compared result respecting to the predetermined signal and an N-1th adjusting signal mismatching the predetermined rule, and stop generating an Nth processing signal when both an Nth compared result respecting to the predetermined signal and an Nth adjusting signal matching the predetermined rule.

15. The frequency adjusting method of claim 11, wherein the second predetermined manner is to generating an N-1th processing signal when an N-1th compared result respecting that both an N-1th adjusting signal and the predetermined signal matching the predetermined rule, and stop generating an N processing signal when an N compared result respecting that the predetermined signal and an N adjusting signal mismatching the predetermined rule.

16. The frequency adjusting method of claim 11, wherein the predetermined rule is that the frequency of N adjusting signal approximately equal to the frequency of the predetermined signal.

17. The frequency adjusting method of claim 11, wherein the predetermined rule is that the difference between the frequency of the N adjusting signal and the frequency of the predetermined signal less than 10%.

18. The frequency adjusting method of claim 11, wherein the frequency adjusting method further comprises step:
(c1) storing the M adjusting signal when both M adjusting signal of the N adjusting signal and the predetermined signal matching the predetermined rule.

19. The frequency adjusting method of claim 18, wherein the specific operation is to get a middle value of the frequency of the M adjusting signal for generating a middle frequency and then generating the operation signal according to the middle frequency.
